(19) United States
(12) Patent Application Publication
(10) Pub. No.: US 2026/0005102 A1
(43) Pub. Date: Jan. 1, 2026

(54) POWER MODULE AND METHOD FOR MANUFACTURING SAME

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/880,991

(22) PCT Filed: Jun. 15, 2023
(86) PCT No.: PCT/KR2023/008234

§ 371 Date: Jan. 3, 2025

(30) Foreign Application Priority Data
Jul. 4, 2022 (KR) 10-2022-0081633

(51) Int. Cl. H01L 23/473; H01L 21/48; H01L 23/15; H01L 23/498; H01L 23/538; H01L 25/16

(52) U.S. Cl. CPC H01L 23/473; H01L 21/4853; H01L 23/15; H01L 23/49811; H01L 23/5385; H01L 23/5386; H01L 25/162

(57) ABSTRACT

The present invention relates to a power module and a method for manufacturing the same. The power module of the present invention may include: an upper ceramic substrate and a lower ceramic substrate; and a flow path part positioned between the upper ceramic substrate and the lower ceramic substrate and provided with multiple flow path channels through which a liquid refrigerant passes, wherein the flow path part may be formed of a metal material. According to the present invention, the flow path part is disposed between the upper and lower ceramic substrates so that effective heat dissipation is possible and miniaturization and weight reduction are possible.

### TECHNICAL FIELD

Embodiments of the present invention relate to a power module and a method for manufacturing the same, and more particularly, to a power module configured to enable effective heat dissipation by disposing a flow path part between upper and lower ceramic substrates, and a method for manufacturing the power module.

### BACKGROUND ART

An electric vehicle typically requires an inverter that converts a direct current voltage supplied by a high-voltage battery into a three-phase alternating current voltage to drive a motor.

The inverter is assembled with a power module configured to regulate a high voltage from a drive battery to a state suitable to the motor and supply the regulated voltage to the motor. The power module includes a semiconductor chip for power conversion. The semiconductor chip generates high-temperature heat due to a high-voltage and high-current operation. If the heat is sustained, the semiconductor chip undergoes degradation and the performance of the power module deteriorates.

To resolve the issues, a heat sink is provided on at least one surface of a ceramic or metal substrate to prevent the thermal degradation of the semiconductor chip through a heat dissipation function of the heat sink. Heat sinks are made of a metal material for heat dissipation. However, even with such metal heat sinks, there is a limit to heat dissipation. Therefore, when heat is generated beyond the limit, cooling efficiency drops sharply, thereby causing a failure. In addition, even for a substrate on which the semiconductor chip is mounted, heat-induced warping may occur, thereby degrading bonding properties.

The foregoing description of the related art is intended to assist in understanding the background of the present invention, and may include an aspect that is not part of a known conventional art.

### DISCLOSURE

### Technical Problem

An object of the present invention is to provide a power module and a method for manufacturing the same, which maximize heat dissipation effect and enable miniaturization and weight reduction by disposing a flow path part employing a direct water cooling configuration between an upper ceramic substrate and a lower ceramic substrate.

### Technical Solution

A power module according to embodiments of the present invention may include: an upper ceramic substrate and a lower ceramic substrate; and a flow path part positioned between the upper ceramic substrate and the lower ceramic substrate and provided with multiple flow path channels through which a liquid refrigerant passes, wherein the flow path part may be formed of a metal material.

Each of the multiple flow path channels may penetrate the interior of the flow path part to extend in a lengthwise direction from one end surface of the flow path part to the other end surface thereof.

Each of the multiple flow path channels may be formed by being penetrated in a direction horizontal to an upper surface of the lower ceramic substrate.

The multiple flow path channels may be disposed to be spaced apart a predetermined distance from each other along a single line.

Each of the multiple flow path channels may be bent in a zigzag shape and extend.

Each of the multiple flow path channels may be formed with a constant cross-sectional shape perpendicular to a direction in which the liquid refrigerant flows.

The upper ceramic substrate may be provided with metal layers on one surface and the other surface of an upper ceramic base, and the lower ceramic substrate may be provided with metal layers on one surface and the other surface of a lower ceramic base.

The upper ceramic substrate may include: a first metal layer and a second metal layer provided on one surface of the upper ceramic base, disposed to be spaced apart from each other, and provided in a circuit pattern shape; and a third metal layer formed across the entire other surface of the upper ceramic base.

The lower ceramic substrate may include: a first metal layer and a second metal layer provided on one surface of the lower ceramic base, disposed to be spaced apart from each other, and provided in a circuit pattern shape; and a third metal layer formed across the entire other surface of the lower ceramic base.

The upper ceramic substrate and the lower ceramic substrate may be disposed such that their respective third metal layers face each other with the flow path part interposed therebetween.

The upper ceramic substrate and the lower ceramic substrate may be disposed such that their respective first metal layers vertically face each other.

In the upper ceramic substrate and the lower ceramic substrate, respectively, the first metal layer may be configured to have a power semiconductor chip mounted thereon, and the second metal layer may be configured to have a drive IC chip mounted thereon.

In the upper ceramic substrate and the lower ceramic substrate, respectively, the first metal layer may have a greater thickness than the second metal layer.

A method for manufacturing a power module may include: preparing an upper ceramic substrate; preparing a lower ceramic substrate; preparing a flow path part provided with multiple flow path channels through which a liquid refrigerant passes; and bonding the upper ceramic substrate to an upper surface of the flow path part and bonding the lower ceramic substrate to a lower surface of the flow path part, wherein in said preparing a flow path part, the flow path part may be formed of a metal material.

In said preparing a flow path part, each of the multiple flow path channels may penetrate the interior of the flow path part to extend in a lengthwise direction from one end surface of the flow path part to the other end surface thereof.

In said preparing an upper ceramic substrate, the upper ceramic substrate may include: a first metal layer and a second metal layer provided on one surface of an upper ceramic base, disposed to be spaced apart from each other, and provided in a circuit pattern shape; and a third metal layer formed across the entire other surface of the upper ceramic base.

In said preparing a lower ceramic substrate, the lower ceramic substrate may include: a first metal layer and a second metal layer provided on one surface of a lower ceramic base, disposed to be spaced apart from each other, and provided in a circuit pattern shape; and a third metal layer formed across the entire other surface of the lower ceramic base.

In said bonding the upper ceramic substrate to an upper surface of the flow path part and bonding the lower ceramic substrate to a lower surface of the flow path part, the upper ceramic substrate, the flow path part, and the lower ceramic substrate may be bonded by means of bonding layers disposed between the upper ceramic substrate and the upper surface of the flow path part, and between the lower surface of the flow path part and the lower ceramic substrate, and the bonding layers may be formed of a material including at least one of Ag, Cu, AgCu, and AgCuTi, or may be formed of an Ag sintering paste.

### Advantageous Effects

The present invention has a configuration in which a flow path part provided with multiple flow path channels, through which a liquid refrigerant passes, is disposed between an upper ceramic substrate and a lower ceramic substrate, and thus may simultaneously cool the upper ceramic substrate and the lower ceramic substrate through the flow path part, Therefore, it is not necessary to dispose a separate heat sink on each of the substrates, thereby enabling miniaturization and weight reduction and reducing costs.

In addition, the present invention may rapidly cool the heat from a power semiconductor chip and a drive IC chip mounted on the upper ceramic substrate and the lower ceramic substrate through the liquid refrigerant passing through the multiple flow path channels provided in the flow path part.

In addition, the present invention may further enhance heat dissipation performance as the flow path part is formed of aluminum or copper having high thermal conductivity.

In addition, the present invention may have a direct water cooling configuration in which the liquid refrigerant continuously circulates and dissipates heat to the outside, thereby effectively dissipating heat, and may suppress a temperature rise of the upper ceramic substrate and the lower ceramic substrate, thereby improving the performance of a power module.

### DESCRIPTION OF DRAWINGS

FIG. 1 is a perspective view illustrating a power module according to embodiments of the present invention.

FIG. 2 is a perspective view of the power module illustrated in FIG. 1, when viewed from the opposite direction.

FIG. 3 is an exploded perspective view of FIG. 2.

FIG. 4 is a front view illustrating the power module according to embodiments of the present invention.

FIG. 5 is a side view schematically illustrating a state in which a power semiconductor chip and a drive IC chip are mounted on the power module according to embodiments of the present invention.

FIG. 6 is a plan view illustrating a portion of a cross-section of a flow path part taken along line A-A′ in FIG. 4.

FIG. 7 is a view illustrating a variation of the flow path part.

FIG. 8 is a conceptual diagram schematically illustrating a configuration in which a connection part is mounted on the power module, and a circulation driving part is connected to the connection part according to embodiments of the present invention.

FIG. 9 is a flowchart illustrating a method for manufacturing the power module according to embodiments of the present invention.

### MODE FOR INVENTION

Preferred embodiments of the present invention will be described in detail below with reference to the accompanying drawings.

The embodiments are provided to more fully describe the present invention to those skilled in the art, and the following embodiments may be modified in various other forms, and the scope of the present invention is not limited to the following embodiments. Rather, these embodiments are provided to make the present invention more thorough and complete and fully convey the spirit of the present invention.

The terminology used herein is for the purpose of describing specific embodiments and is not intended to limit the present invention. In addition, as used herein, singular forms may include plural forms, unless the context clearly indicates otherwise.

In the description of embodiments, where each layer (film), region, pattern, or structure is described as being formed “on” or “under” a substrate, layer (film), region, pad, or pattern, “on” and “under” include both “directly” formed and “indirectly formed “with another layer interposed therebetween.” In addition, the reference for each layer being on or under is, in principle, based on the drawings.

The drawings are intended only to help understand the spirit of the present invention, and should not be construed as limiting the scope of the present invention. In addition, relative thickness, length, or relative size in the drawings may be exaggerated for convenience and clarity of description.

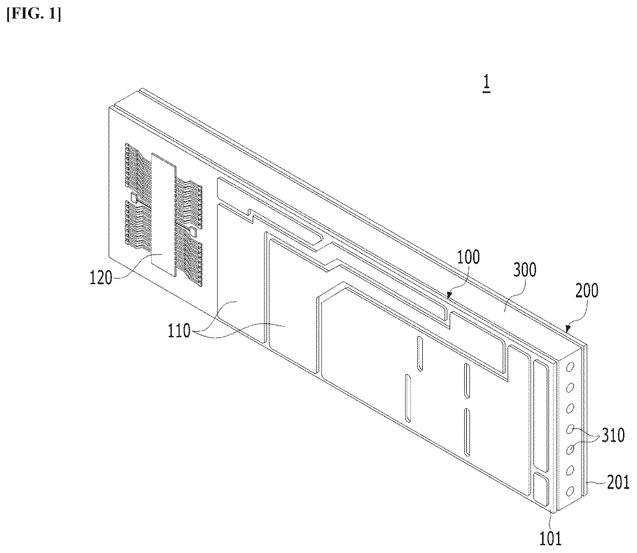

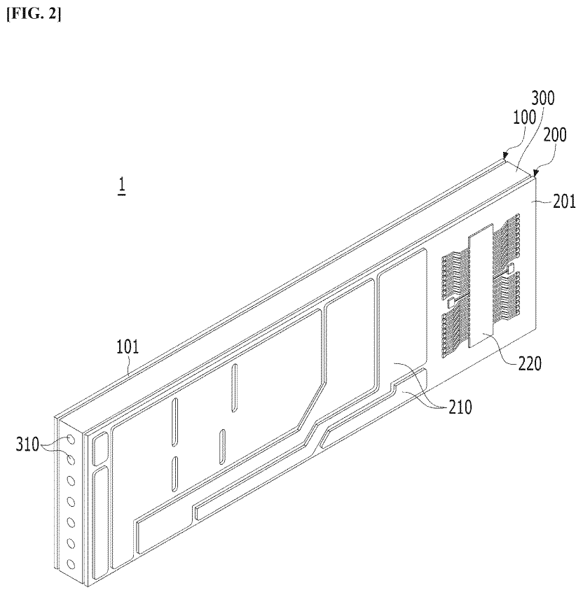

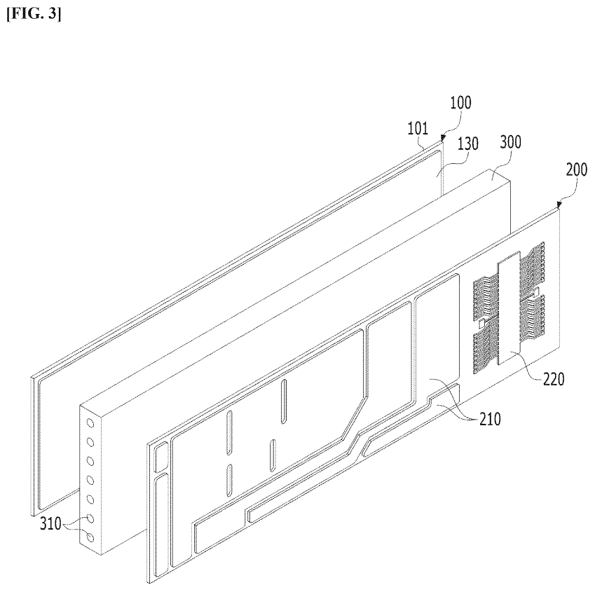

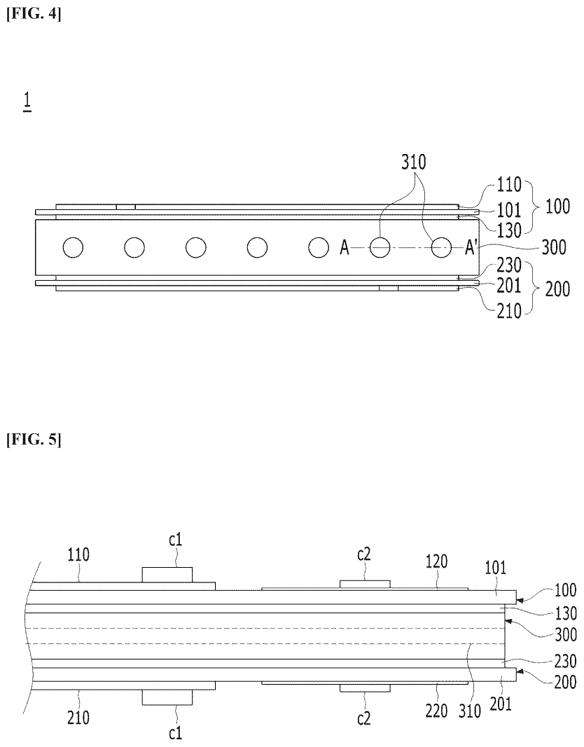

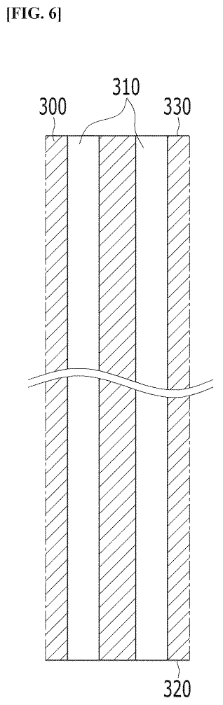

FIG. 1 is a perspective view illustrating a power module according to embodiments of the present invention. FIG. 2 is a perspective view of the power module illustrated in FIG. 1, when viewed from the opposite direction. FIG. 3 is an exploded perspective view of FIG. 2. FIG. 4 is a front view illustrating the power module according to embodiments of the present invention. FIG. 5 is a side view schematically illustrating a state in which a power semiconductor chip and a drive IC chip are mounted on the power module according to embodiments of the present invention.

As illustrated in FIGS. 1 to 4, a power module 1 according to embodiments of the present invention may be configured to include an upper ceramic substrate 100, a lower ceramic substrate 200, and a flow path part 300.

The upper ceramic substrate 100 and the lower ceramic substrate 200 may be any one of an active metal brazing (AMB) substrate, a direct bonding copper (DBC) substrate, a thick printing copper (TPC) substrate, and a DBA substrate. In terms of durability and heat dissipation efficiency, an AMB substrate or a DBC substrate is the most suitable.

For example, the upper ceramic substrate 10 may be configured to include an upper ceramic base 101 and metal layers 110, 120, and 130 provided on one surface and the other surface of the upper ceramic base 101. The lower ceramic substrate 200 is positioned below the upper ceramic substrate 100, and may be configured to include a lower ceramic base 201 and metal layers 210, 220, and 230 provided on one surface and the other surface of the lower ceramic base 201.

The metal layers 110, 120, and 130 of the upper ceramic substrate 100 may be formed by brazing metal foil onto one surface and the other surface of the upper ceramic base 101 and then etching or machining the metal foil into a designed shape. The upper ceramic base 101 may be exemplified by being any one of alumina (Al₂O₃), AlN, SiN, and Si₃N₄. The thickness of the upper ceramic base 101 is 0.3 mm to 0.4 mm. For example, the thickness of the upper ceramic base 101 may be 0.32 mm or 0.38 mm. In the upper ceramic substrate 100, the first metal layer 110 and the second metal layer 120 may be provided on one surface of the upper ceramic base 101, and may be disposed to be spaced apart from each other. The first metal layer 110 and the second metal layer 120 may be provided in a circuit pattern shape. In addition, the first metal layer 110 may be formed to have a larger area than the second metal layer 120. In the upper ceramic substrate 100, the third metal layer 130 may be provided on the other surface of the upper ceramic base 101. The first metal layer 110 and the third metal layer 130 may be exemplified by being made of one of Cu, Cu alloy (CuMo, etc.), and Al. In addition, the second metal layer 120 may be exemplified by being made of one of Ag, Au, Pt, Cu, Ag alloy, and carbon black.

The third metal layer 130 of the upper ceramic substrate 100 may be bonded to the flow path part 300 by means of a bonding layer (not illustrated). The bonding layer may be disposed between the third metal layer 130 of the upper ceramic substrate 100 and an upper surface of the flow path part 300. The thickness of the bonding layer may be formed thin enough to not affect the height of the power module 1. For example, the thickness of the bonding layer may be 0.3 μm to 3.0 μm.

The bonding layer may be a brazing bonding layer or an Ag sintering bonding layer made of a material including at least one of Ag, Cu, AgCu, and AgCuTi. When the bonding layer is a brazing bonding layer, the brazing bonding layer may be formed by using any one of the following methods: plating, paste application, and foil attachment. The brazing may be performed at a temperature of 900° C. or higher for 1 to 2 hours. When the bonding layer is an Ag sintering bonding layer, the Ag sintering bonding layer may be formed by applying Ag sintering paste, by using a film printed with Ag sintering paste to transfer Ag sintering paste, or the like. The Ag sintering bonding may be performed at a temperature of 200° C. to 250° C. for 15 to 30 minutes, wherein a pressure of 10 MPa to 15 MPa may be applied. Ag, AgCu, and AgCuTi have high thermal conductivity, which may play a role in increasing bonding strength, while facilitating heat transfer between the upper ceramic substrate 100 and the flow path part 300, thereby enhancing heat dissipation efficiency.

As illustrated in FIG. 3, the third metal layer 130 of the upper ceramic substrate 100 may be in the form of a flat plate, and may be formed across the entire other surface of the upper ceramic base 101 to facilitate heat exchange with the flow path part 300. The third metal layer 130 of the upper ceramic substrate 100 may have one side region facing the first metal layer 110 and the other side region facing the second metal layer 120.

The lower ceramic substrate 200 may have the metal layers 210, 220, and 230 provided on one surface and the other surface of the lower ceramic base 201. The metal layers 210, 220, and 230 of the lower ceramic substrate 200 may be formed by brazing metal foil onto one surface and the other surface of the lower ceramic base 201 and then etching or machining the metal foil into a designed shape. The lower ceramic base 201 may be exemplified by being any one of alumina (Al₂O₃), AlN, SiN, and Si₃N₄. The thickness of the lower ceramic base 201 is 0.3 mm to 0.4 mm. For example, the thickness of the lower ceramic base 201 may be 0.32 mm or 0.38 mm. In the lower ceramic substrate 200, the first metal layer 210 and the second metal layer 220 may be provided on one surface of the lower ceramic base 201, and may be disposed to be spaced apart from each other. The first metal layer 210 and the second metal layer 220 may be provided in a circuit pattern shape. In addition, the first metal layer 210 may be formed to have a larger area than the second metal layer 220. The third metal layer 230 of the lower ceramic substrate 200 may be provided on the other surface of the lower ceramic base 201. The first metal layer 210 and the third metal layer 230 may be exemplified by being made of one of Cu, Cu alloy (CuMo, etc.), and Al. In addition, the second metal layer 220 may be exemplified by being made of one of Ag, Au, Pt, Cu, Ag alloy, and carbon black.

The third metal layer 230 of the lower ceramic substrate 200 may be bonded to the flow path part 300 by means of a bonding layer (not illustrated). The bonding layer may be disposed between a lower surface of the flow path part 300 and the third metal layer 230 of the lower ceramic substrate 200. The thickness of the bonding layer may be formed thin enough to not affect the height of the power module. For example, the thickness of the bonding layer may be 0.3 μm to 3.0 μm.

The bonding layer may be a brazing bonding layer or an Ag sintering bonding layer made of a material including at least one of Ag, Cu, AgCu, and AgCuTi. When the bonding layer is a brazing bonding layer, the brazing bonding layer may be formed using any one of the following methods: plating, paste application, and foil attachment. The brazing may be performed at a temperature of 900° C. or higher for 1 to 2 hours. When the bonding layer is an Ag sintering bonding layer, the Ag sintering bonding layer may be formed by applying Ag sintering paste, by using a film printed with an Ag sintering paste to transfer Ag sintering paste, or the like. The Ag sintering bonding may be performed at a temperature of 200° C. to 250° C. for 15 to 30 minutes, wherein a pressure of 10 MPa to 15 MPa may be applied. Ag, AgCu, and AgCuTi have high thermal conductivity, which may play a role in increasing bonding strength, while facilitating heat transfer between the lower ceramic substrate 200 and the flow path part 300, thereby enhancing heat dissipation efficiency.

Although not illustrated in detail, the third metal layer 230 of the lower ceramic substrate 200 may be in the form of a flat plate in the same way as the third metal layer 130 of the upper ceramic substrate 100 illustrated in FIG. 3, and may be formed across the entire other surface of the lower ceramic base 201 to facilitate heat exchange with the flow path part 300. The third metal layer 230 of the lower ceramic substrate 200 may have one side region facing the first metal layer 210 and the other side region facing the second metal layer 220.

As illustrated in FIG. 4, the upper ceramic substrate 100 and the lower ceramic substrate 200 may be disposed such that their respective third metal layers 130 and 230 face each other with the flow path part 300 interposed therebetween. In addition, referring to FIGS. 1, 2, and 4, the upper ceramic substrate 100 and the lower ceramic substrate 200 may be disposed such that their respective first metal layers 110 and 210 vertically face each other.

Referring to FIG. 5, in the upper ceramic substrate 100 and the lower ceramic substrate 200, respectively, the first metal layers 110 and 210 may be configured to have a power semiconductor chip c1 mounted thereon. For example, the first metal layers 110 and 210 may have the power semiconductor chip c1 mounted thereon, which is based on SiC and GaN that may meet the requirements such as use in high-voltage, high-current, high-temperature operation, and high-frequency environments, high-speed switching, minimized power loss, and compact chip size. The first metal layers 110 and 210 may have various devices, other than SiC and GaN chips, mounted thereon, such as a Si chip, a metal oxide semiconductor field effect transistor (MOSFET), an insulated gate bipolar transistor (IGBT), a junction field effect transistor (JFET), a high electric mobility transistor (HEMT), and a diode. The first metal layers 110 and 210 may have a plurality of electrodes disposed thereon in a predetermined pattern.

In addition, in the upper ceramic substrate 100 and the lower ceramic substrate 200, respectively, the second metal layers 120 and 220 may be configured to have a drive IC chip c2 mounted thereon. For example, the second metal layers 120 and 220 may have driving, electrical, and electronic control devices based on silicon-on-insulator (SOI) mounted thereon.

In the upper ceramic substrate 100 and the lower ceramic substrate 200, respectively, the first metal layers 110 and 210, which are configured to have the power semiconductor chip c1 mounted thereon, are portions where high current flows, while the second metal layers 120 and 220, which are configured to have the drive IC chip c2 mounted thereon, are portions where low current flows. Therefore, the first metal layers 110 and 210 may be formed to have a greater thickness than the second metal layers 120 and 220. For example, the thickness of the first metal layers 110 and 210 may be, but is not limited to, approximately 0.3 mm, and the thickness of the second metal layers 120 and 220 may be, but is not limited to, approximately 20 μm.

As such, each of the upper ceramic substrate 100 and the lower ceramic substrate 200 may be a ceramic substrate with a dual-electrode configuration on which two types of chips, which are the power semiconductor chip c1 and the drive IC chip c2, are mounted. Such a ceramic substrate with a dual-electrode configuration enables a smaller size and weight reduction compared to a case where a drive IC module and a power module are provided separately.

The power module 1 according to embodiments of the present invention has a configuration in which the flow path part 300 provided with multiple flow path channels 310, through which a liquid refrigerant passes, is disposed between the upper ceramic substrate 100 and the lower ceramic substrate 200, thereby maximizing heat dissipation efficiency. That is, conventionally, both a heat sink configured to dissipate heat from the upper ceramic substrate 100 and a heat sink configured to dissipate heat from the lower ceramic substrate 200 should be provided separately, but since the power module 1 according to embodiments of the present invention may simultaneously cool the upper ceramic substrate 100 and the lower ceramic substrate 200 through a single flow path part 300, it is not necessary to dispose a separate heat sink on each of the substrates, thereby enabling miniaturization and weight reduction and reducing costs. In addition, the power module 1 according to embodiments of the present invention may rapidly cool the heat from the power semiconductor chip c1 and the drive IC chip c2 mounted on the upper ceramic substrate 100 and the lower ceramic substrate 200 through a liquid refrigerant passing through the multiple flow path channels 310 provided in the flow path part 300.

The flow path part 300 may be formed of a metal material. For example, the flow path part 300 may be formed of aluminum or copper, which may transfer heat quickly. If the flow path part 300 is formed of aluminum or copper, the heat dissipation performance may be further enhanced. The thickness of the flow path part 300 may vary depending on the design of the flow channel 310, but is preferably at least 2 mm.

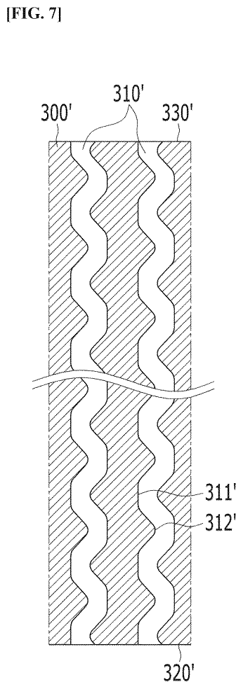

FIG. 6 is a plan view illustrating a portion of a cross-section of a flow path part taken along line A-A′ in FIG. 4. FIG. 7 is a view illustrating a variation of the flow path part.

Referring to FIG. 6, each of the multiple flow path channels 310 may penetrate the interior of the flow path part 300 to extend in a lengthwise direction from one end surface 320 of the flow path part 300 to the other end surface 330 thereof.

The multiple flow path channels 310 may be disposed to be spaced apart a predetermined distance from each other along a single line. Each of the multiple flow path channels 310 may be formed by being penetrated in a direction horizontal to an upper surface of the lower ceramic substrate 200. In addition, each of the multiple flow path channels 310 may be formed with a constant cross-sectional shape perpendicular to a direction in which the liquid refrigerant flows. Such a configuration of the flow path channels 310 ensures a constant shape of the flow path channels 310 along a direction in which the liquid refrigerant flows, so that the flow path channels 310 narrow in a certain section, thereby reducing the likelihood of blockage of the flow path channels 310.

The present embodiment illustrates an example where each of the multiple flow path channels 310 has a circular cross-section and the flow path channels 310 extend in a straight line, but the shape, number, and spacing in the arrangement of the flow path channels 310 are not limited thereto. For example, the cross-section of the flow path channels 310 may be formed in a rectangle, a polygon, or other shapes, and the number of the flow path channels 310 may vary, such as 3, 10, or the like. In addition, the spacing between the multiple flow path channels 310 may be designed to vary depending on the number of the flow path channels 310. The shape of the flow path part 300 may be implemented through processes such as machining, molding, and die casting.

FIG. 7 illustrates a variation of a flow path part 300′, wherein each of multiple flow path channels 310′ provided in the flow path part 300′ may be configured to have a zigzag shape formed by alternately disposing first portions 311′ in a concave shape and second portions 312′ in a convex shape. That is, each of the multiple flow path channels 310′ may be bent in a zigzag shape and extend in a lengthwise direction from one end surface 320′ of the flow path part 300 to the other end surface 330′ thereof. When the flow path channels 310′ are bent in a zigzag shape and extend in this way, the liquid refrigerant flows at a different speed compared to the flow path channels 310 extending in a straight line shown in FIG. 6. When the shape of the flow path channels 310′ extending in the lengthwise direction of the flow path part 300′ changes in this way, the flow rate of the liquid refrigerant changes. Therefore, the shape of the flow path channels 310′ may be designed to allow the refrigerant to flow at a desired flow rate.

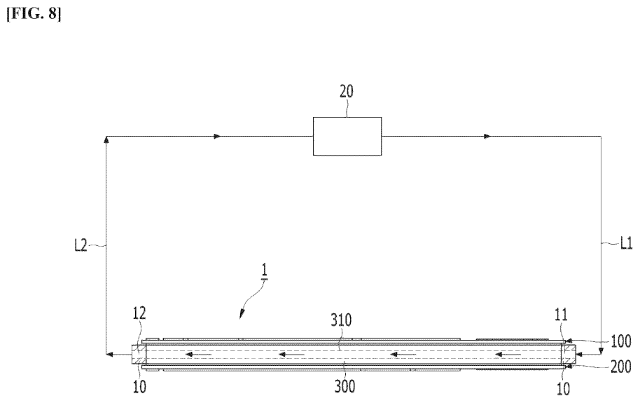

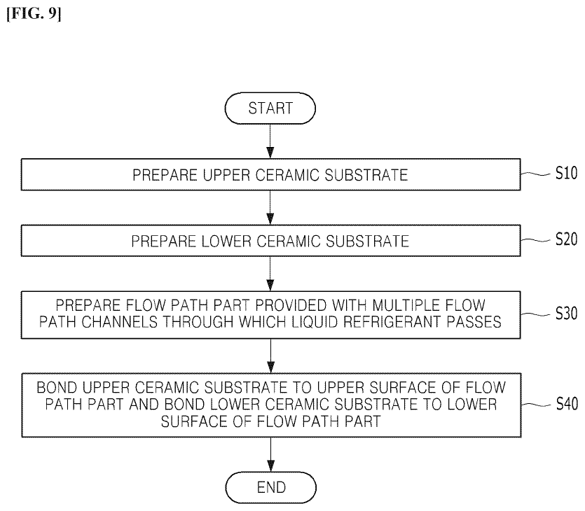

FIG. 8 is a conceptual diagram schematically illustrating a configuration in which a connection part is mounted on the power module according to embodiments of the present invention, and a circulation driving part is connected to the connection part.

Referring to FIG. 8, each of the multiple flow path channels 310 may have connection parts 10 installed at both ends thereof for the inlet and outlet of the liquid refrigerant. Although not illustrated in detail, the connection parts 10 may be installed on the both end surfaces 320 and 330 in the lengthwise direction of the flow path part 300. The connection part 10 may be provided with an inlet portion 11 communicating with one end of the flow path channel 310 in the lengthwise direction thereof and an outlet portion 12 communicating with the other end of the flow path channel 310 in the lengthwise direction thereof.

Although not illustrated in detail, the flow path part 300 may be installed such that the remaining portion, except for portions through which the liquid refrigerant flows in and out, is sealed. That is, the liquid refrigerant only flows in and out through the flow path part 300, and does not flow into the upper ceramic substrate 100 and the lower ceramic substrate 200.

A circulation driving part 20 may be connected to the inlet portion 11 and the outlet portion 12, and may circulate the liquid refrigerant by using the driving force of a pump (not illustrated). Here, the inlet portion 11 may be connected to the circulation driving part 20 through a first circulation line L1, and the outlet portion 12 may be connected to the circulation driving part 20 through a second circulation line L2. That is, the circulation driving part 20 may continuously circulate the liquid refrigerant along the circulation path including the first circulation line L1, the inlet portion 11, the flow path channel 310, the outlet portion 12, and the second circulation line L2. Here, the liquid refrigerant may be, but is not limited to, deionized water, and liquid nitrogen, alcohol, or other solvents may be used as needed.

Referring to the circulation path of the liquid refrigerant indicated by the arrows in FIG. 8, the liquid refrigerant supplied from the circulation driving part 20 may flow into the inlet portion 11 through the first circulation line L1, and the liquid refrigerant flowing into the flow path channel 310 through the inlet portion 11 may move along the multiple flow path channels 310 and be discharged through the outlet portion 12, and then may move back to the circulation driving part 20 through the second circulation line L2. Although not illustrated, the liquid refrigerant may pass through a heat exchanger (not illustrated) while circulating along the circulation path. While this occurs, the heat exchanger may lower the temperature of the liquid refrigerant that has increased in temperature while passing through the flow path channels 310. The liquid refrigerant cooled in the heat exchanger may be supplied back to the first circulation line L1 by the circulation driving part 20, and may flow into the multiple flow path channels 310 through the inlet portion 11. The liquid refrigerant may cool the heat transferred from the upper ceramic substrate 100 and the lower ceramic substrate 200 while passing through the multiple flow path channels 310, and may be discharged through the outlet portion 12.

In this way, the multiple flow path channels 310 have a direct water cooling configuration in which the liquid refrigerant supplied from the circulation driving part 20 continuously circulates and dissipates heat to the outside. Due to this cooling configuration, heat generated by power semiconductor chips, drive IC chips, etc. mounted on the upper ceramic substrate 100 and the lower ceramic substrate 200 may be effectively dissipated, and a temperature rise of the upper ceramic substrate 100 and the lower ceramic substrate 200 may be suppressed, thereby improving the performance of the power module 1.

The power module 1 according to embodiments of the present invention may use a single flow path part 300 to simultaneously dissipate heat from the upper ceramic substrate 100 and the lower ceramic substrate 200 bonded to the upper and lower surfaces of the flow path part 300, respectively. Therefore, it is not necessary to have separate heat sinks configured to dissipate heat from the upper ceramic substrate 100 and the lower ceramic substrate 200, respectively, and rapid cooling is possible through a single flow path part 300, thereby not only reducing costs but also enabling miniaturization.

FIG. 9 is a flowchart illustrating a method for manufacturing the power module according to embodiments of the present invention.

A method for manufacturing the power module according to embodiments of the present invention may include, as illustrated in FIG. 9, a step of preparing the upper ceramic substrate 100 (S10), a step of preparing the lower ceramic substrate 200 (S20), a step of preparing the flow path part 300 provided with the multiple flow path channels 310 through which the liquid refrigerant passes (S30), and a step of bonding the upper ceramic substrate 100 to the upper surface of the flow path part 300 and bonding the lower ceramic substrate 200 to the lower surface of the flow path part 300 (S40). Here, each of the steps may be performed sequentially, in a different order, or substantially simultaneously.

In the step of preparing the upper ceramic substrate 100 (S10), the upper ceramic substrate 100 may be provided with the upper ceramic base 101 and the metal layers 110, 120, and 130 on one surface and the other surface of the upper ceramic base 101 to enhance the heat dissipation efficiency of the heat generated from the power semiconductor chip c1 and the drive IC chip c2. The metal layers 110, 120, and 130 of the upper ceramic substrate 100 may be formed by brazing metal foil onto one surface and the other surface of the upper ceramic base 101 and then etching or machining the metal foil into a designed shape. In the upper ceramic substrate 100, the first metal layer 110 and the second metal layer 120 may be provided on one surface of the upper ceramic base 101, and may be disposed to be spaced apart from each other. The first metal layer 110 and the second metal layer 120 may be provided in a circuit pattern shape. The third metal layer 130 may be provided on the other surface of the upper ceramic base 101. Here, the third metal layer 130 may be formed across the entire other surface of the upper ceramic base 101 to facilitate heat exchange with the flow path part 300.

In the step of preparing the lower ceramic substrate 200 (S20), the lower ceramic substrate 200 may be provided with the lower ceramic base 201 and the metal layers 210, 220, and 230 on one surface and the other surface of the lower ceramic base 201 to enhance the heat dissipation efficiency of the heat generated from the power semiconductor chip c1 and the drive IC chip c2. The metal layers 210, 220, and 230 of the lower ceramic substrate 200 may be formed by brazing metal foil onto one surface and the other surface of the lower ceramic base 201 and then etching or machining the metal foil into a designed shape. In the lower ceramic substrate 200, the first metal layer 210 and the second metal layer 220 may be provided on one surface of the lower ceramic base 201, and may be disposed to be spaced apart from each other. The first metal layer 210 and the second metal layer 220 may be provided in a circuit pattern shape. The third metal layer 230 may be provided on the other surface of the lower ceramic base 201. Here, the third metal layer 230 may be formed across the entire other surface of the lower ceramic base 201 to facilitate heat exchange with the flow path part 300.

In the step of preparing the flow path part 300 (S30), the flow path part 300 may be formed of aluminum or copper, which may transfer heat quickly. If the flow path part 300 is formed of aluminum or copper, the heat dissipation performance may be further enhanced. The flow path part 300 may be provided with the multiple flow path channels 310 through which the liquid refrigerant passes. Each of the multiple flow path channels 310 may penetrate the interior of the flow path part 300 to extend in a lengthwise direction from the one end surface 320 of the flow path part 300 to the other end surface 330 thereof. The shape, number, and spacing in the arrangement of the multiple flow path channels 310 are not limited to the embodiments of the present invention, but may vary depending on the flow rate of the liquid refrigerant, cooling efficiency, and the like. The shape of the flow path part 300 may be implemented through processes such as machining, molding, and die casting.

In the step of bonding the upper ceramic substrate 100 to the upper surface of the flow path part 300 and bonding the lower ceramic substrate 200 to the lower surface of the flow path part 300 (S40), the upper ceramic substrate 100, the flow path part 300, and the lower ceramic substrate 200 may be bonded by means of bonding layers (not illustrated) disposed between the upper ceramic substrate 100 and the upper surface of the flow path part 300, and between the lower surface of the flow path part 300 and the lower ceramic substrate 200. The bonding layer may be a brazing bonding layer or an Ag sintering bonding layer made of a material including at least one of Ag, Cu, AgCu, and AgCuTi. When the bonding layer is a brazing bonding layer, the brazing bonding layer may be formed using any one of the following methods: plating, paste application, and foil attachment. The brazing may be performed at a temperature of 900° C. or higher for 1 to 2 hours. When the bonding layer is an Ag sintering bonding layer, the Ag sintering bonding layer may be formed by applying Ag sintering paste, by using a film printed with an Ag sintering paste to transfer Ag sintering paste, or the like. The Ag sintering bonding may be performed at a temperature of 200° C. to 250° C. for 15 to 30 minutes, wherein a pressure of 10 MPa to 15 MPa may be applied. Ag, AgCu, and AgCuTi have high thermal conductivity, which may play a role in increasing bonding strength, while facilitating heat transfer, thereby enhancing heat dissipation efficiency.

As such, the power module according to the embodiments of the present invention has the upper ceramic substrate 100 and the lower ceramic substrate 200 integrated on the upper and lower surfaces of the flow path part 300, and has a configuration that allows direct cooling of the heat generated from the power semiconductor chip c1 and the drive IC chip c2 mounted on the upper and lower ceramic substrates 100 and 200, thereby implementing weight reduction and miniaturization while improving heat dissipation performance.

The above description is merely an exemplary description of the technical spirit of the present invention, and it will be apparent to those skilled in the art that various modifications and variations are possible without departing from the essential features of the present invention. Therefore, the embodiments disclosed herein are intended to describe and not to limit the technical spirit of the present invention, and the scope of the technical spirit of the present invention is not limited by these embodiments. The protection scope of the present invention should be construed in accordance with the following claims, and all the technical spirit within the scope of the equivalents thereof should be construed as being included within the scope of rights of the present invention.

1. A power module comprising:
an upper ceramic substrate and a lower ceramic substrate; and
a flow path part positioned between the upper ceramic substrate and the lower ceramic substrate and provided with multiple flow path channels through which a liquid refrigerant passes,
wherein the flow path part is formed of a metal material.

2. The power module of claim 1, wherein each of the multiple flow path channels penetrates the interior of the flow path part to extend in a lengthwise direction from one end surface of the flow path part to the other end surface thereof.

3. The power module of claim 1, wherein each of the multiple flow path channels is formed by being penetrated in a direction horizontal to an upper surface of the lower ceramic substrate.

4. The power module of claim 1, wherein the multiple flow path channels are disposed to be spaced apart a predetermined distance from each other along a single line.

5. The power module of claim 2, wherein each of the multiple flow path channels is bent in a zigzag shape and extend.

6. The power module of claim 1, wherein each of the multiple flow path channels is formed with a constant cross-sectional shape perpendicular to a direction in which the liquid refrigerant flows.

7. The power module of claim 1, wherein:
the upper ceramic substrate is provided with metal layers on one surface and the other surface of an upper ceramic base, and
the lower ceramic substrate is provided with metal layers on one surface and the other surface of a lower ceramic base.

8. The power module of claim 7, wherein the upper ceramic substrate comprises:
a first metal layer and a second metal layer provided on one surface of the upper ceramic base, disposed to be spaced apart from each other, and provided in a circuit pattern shape; and
a third metal layer formed across the entire other surface of the upper ceramic base.

9. The power module of claim 8, wherein the lower ceramic substrate comprises:
a first metal layer and a second metal layer provided on one surface of the lower ceramic base, disposed to be spaced apart from each other, and provided in a circuit pattern shape; and
a third metal layer formed across the entire other surface of the lower ceramic base.

10. The power module of claim 9, wherein the upper ceramic substrate and the lower ceramic substrate are disposed such that their respective third metal layers face each other with the flow path part interposed therebetween.

11. The power module of claim 9, wherein the upper ceramic substrate and the lower ceramic substrate are disposed such that their respective first metal layers vertically face each other.

12. The power module of claim 9, wherein in the upper ceramic substrate and the lower ceramic substrate, respectively, the first metal layer is configured to have a power semiconductor chip mounted thereon, and the second metal layer is configured to have a drive IC chip mounted thereon.

13. The power module of claim 9, wherein in the upper ceramic substrate and the lower ceramic substrate, respectively, the first metal layer has a greater thickness than the second metal layer.

14. A method for manufacturing a power module, the method comprising:
preparing an upper ceramic substrate;
preparing a lower ceramic substrate;
preparing a flow path part provided with multiple flow path channels through which a liquid refrigerant passes; and
bonding the upper ceramic substrate to an upper surface of the flow path part and bonding the lower ceramic substrate to a lower surface of the flow path part,
wherein in said preparing a flow path part, the flow path part is formed of a metal material.

15. The method of claim 14, wherein in said preparing a flow path part, each of the multiple flow path channels penetrates the interior of the flow path part to extend in a lengthwise direction from one end surface of the flow path part to the other end surface thereof.

16. The method of claim 14, wherein in said preparing an upper ceramic substrate, the upper ceramic substrate comprises:
a first metal layer and a second metal layer provided on one surface of an upper ceramic base, disposed to be spaced apart from each other, and provided in a circuit pattern shape; and
a third metal layer formed across the entire other surface of the upper ceramic base.

17. The method of claim 14, wherein in said preparing a lower ceramic substrate, the lower ceramic substrate comprises:
a first metal layer and a second metal layer provided on one surface of a lower ceramic base, disposed to be spaced apart from each other, and provided in a circuit pattern shape; and
a third metal layer formed across the entire other surface of the lower ceramic base.

18. The method of claim 14, wherein in said bonding the upper ceramic substrate to an upper surface of the flow path part and bonding the lower ceramic substrate to a lower surface of the flow path part,
the upper ceramic substrate, the flow path part, and the lower ceramic substrate are bonded by means of bonding layers disposed between the upper ceramic substrate and the upper surface of the flow path part, and between the lower surface of the flow path part and the lower ceramic substrate, and
the bonding layers are formed of a material comprising at least one of Ag, Cu, AgCu, and AgCuTi, or is formed of an Ag sintering paste.
